(19) United States
(12) Patent Application Publication
(10) Pub. No.: US 2026/0114056 A1
(43) Pub. Date: Apr. 23, 2026

(54) CARRIER BOARD WITH LIGHT SOURCE IMAGE MODULE, INTEGRATED CARRIER BOARD, AND COMPACT MICRO LIGHT SOURCE IMAGE MODULE

(71) Applicant: Medimaging Integrated Solution, Inc., Hsinchu (TW)

(72) Inventors: Shangyi WU, Hsinchu (TW); Jiunwei CHEN, Hsinchu (TW); Hsin-Hsien Hsieh, Hsinchu (TW)

(21) Appl. No.: 18/921,495

(22) Filed: Oct. 21, 2024

(30) Foreign Application Priority Data
Nov. 3, 2023 (TW) 112211973

(51) Int. Cl. H01L 27/146; H01L 31/02; H01L 31/12

(52) U.S. Cl. CPC H10F 39/198; H10F 55/18; H10F 77/933

(57) ABSTRACT

A carrier board with light source image module includes a substrate, a cavity, a perforated section, an image sensor, and a light-emitting device. The substrate has a first surface and a second surface, which are opposite to each other. The cavity is disposed on the substrate and has a bottom surface. The altitude of the bottom surface is lower than the first surface. The perforated section is disposed on at least a part of the cavity, penetrating the first surface and the second surface. The image sensor is partially located in the cavity and partially located in the perforated section. The altitude of the surface of the image sensor is higher than the first surface. The light-emitting device is disposed on the first surface and adjacent to the image sensor. The surface of the light-emitting device is between the first surface and the surface of the image sensor.

### BACKGROUND OF THE INVENTION

### 1. Field of the Invention

The present invention provides a carrier board with light source image module and a light source-imaging module, particularly a carrier board with light source image module, an integrated carrier board, and a compact micro light source image module.

### 2. Description of the Prior Art

In the conventional light source-imaging module, the heights of the light-emitting diode and the image sensor are fixed and hard to adjust. Thus, the parameters of light source and illumination are less likely to optimize.

In some conventional technologies, the CMOS image sensor module (CIS Module) and LED are disposed on a flexible printed circuit (FPC). However, the conventional technologies confront the following problems: (1) no light shield material is arranged between the CIS module and LED, which makes light of LED enter the image sensor and generates stray light; (2) the position of LED may affect image quality; too low a position of LED may make a shadow appear; (3) a CAP may be formed over the CIS module and LED, which have been disposed on the FPC, to function as light retard layer; in such a case, if the position of LED is required to rise, the FPC should be bent and then fixed; thus, the size of the module will be too large to assemble.

A resin material should be filled into the gap between the image sensor and CAP to fix them. Therefore, a sufficient space should be preserved between the image sensor and CAP, allowing a needle to reach the deep of the gap for filling the resin material. However, the preserved space will enlarge the module size and impair the application to small-size endoscope. If CAP is used to cover the image sensor and LED, several cycles of resin filling processes are required to fix CAP and fill the cavities between the image sensor and LED. Thus, the fabrication efficient is poor.

Accordingly, the present invention proposes a carrier board with light source image module, an integrated carrier board, and a compact micro light source image module to overcome the abovementioned problems.

### SUMMARY OF THE INVENTION

Considering the abovementioned problems, the primary objective of the present invention is to provide a carrier board with a light source image module, wherein the module size is reduced and the early stage preparing processes are omitted, whereby the production hours, the production stages and the production cost are decreased, and the yield is increased.

In order to achieve the abovementioned objective, the present invention provides a carrier board with a light source image module, which comprises a substrate, a cavity, a perforated section, an image sensor, and a light-emitting device. The substrate has a first surface and a second surface opposite to the first surface. The cavity is formed on the substrate and has a bottom surface. The altitude of the bottom surface is lower than the altitude of the first surface. The perforated section is formed on at least a portion of the cavity. The perforated section penetrates through the first surface and the second surface and interconnects with at least a portion of the cavity. The image sensor is partially disposed in the cavity and partially disposed in the perforated section. The altitude of the image sensor is higher than the altitude of the first surface. The light-emitting device is disposed on a position of the first surface, which is adjacent to the image sensor. The top surface of the light-emitting device is between the first surface and the surface of the image sensor.

According to the abovementioned objective, the present invention also provides a compact micro light source image module, which is generated via cutting the abovementioned carrier board with a light source image module. The compact micro light source image module comprises an interposer, an image sensor, a light-emitting device, and an encapsulation body. The interposer includes a bottom base and at least one side carrier, which are generated via cutting the substrate. The bottom base is formed by a portion of the cut cavity. The at least one side carrier is formed by a portion of the substrate, which neighbors the cavity. One side of the bottom base is joined with the side carrier. The image sensor is disposed on the bottom base. The light-emitting device is disposed on the surface of the at least one side carrier. The encapsulation body covers the image sensor except the perimeter of the image sensor, which is corresponding to the at least one side carrier, and the surround of the light-emitting device.

According to the abovementioned objective, the present invention also provides an integrated carrier board with light source image modules, which comprises a plurality of the abovementioned carrier boards with a light source image module, wherein the plurality of carrier board with a light source image modules is integrated into an integral body to function as an integrated carrier board.

According to the abovementioned objective, the present invention further provides a compact micro light source image module, which is generated via cutting the abovementioned integrated carrier board with light source image modules. The compact micro light source image module comprises an interposer, an image sensor, a light-emitting device, and an encapsulation body. The interposer includes a bottom base and at least one side carrier, which are generated via cutting the substrate. The bottom base is formed by a portion of the cut cavity. The at least one side carrier is formed by a portion of the substrate, which neighbors the cavity. One side of the bottom base is joined with the side carrier. The image sensor is disposed on the bottom base. The light-emitting device is disposed on the surface of the at least one side carrier. The encapsulation body covers the image sensor except the perimeter of the image sensor, which is corresponding to the at least one side carrier, and the surround of the light-emitting device.

In summary, the present invention provides a carrier board with a light source image module, an integrated carrier board, and a compact micro light source image module, whereby to simplify the fabrication process, decrease the production stages, promote the yield, and reduce the fabrication cost.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

The foregoing conceptions and their accompanying advantages of this invention will become more readily appreciated after being better understood by referring to the following detailed description, in conjunction with the accompanying drawings, wherein:

FIG. 1A, FIG. 1B, and FIG. 1C are respectively a perspective view, a top view and a schematic diagram of a first embodiment of the carrier board with a light source image module of the present invention;

FIG. 1D is a sectional view taken along LA-A′ in FIG. 1B;

FIG. 2A and FIG. 2B are diagrams schematically showing the substrate where the image sensor and the light-emitting device have not been disposed in the first embodiment of the carrier board with a light source image module of the present invention;

FIG. 3A and FIG. 3B are respectively a perspective view and a schematic diagram showing the carrier board with a light source image module including the encapsulation body in the first embodiment of the present invention;

FIG. 4A and FIG. 4B are respectively a perspective view and a schematic diagram showing the carrier board with a light source image module including the encapsulation body in another embodiment of the present invention;

FIG. 5A is a diagram schematically showing a first embodiment of the compact micro light source image module of the present invention, wherein the compact micro light source image module is obtained via cutting the carrier board with a light source image module;

FIG. 5B and FIG. 5C are respectively a perspective view and a top view showing the first embodiment of the compact micro light source image module of the present invention;

FIG. 6A and FIG. 6B are respectively a perspective view and a top view of a second embodiment of the carrier board with a light source image module of the present invention;

FIG. 7A is a diagram schematically showing a second embodiment of the compact micro light source image module of the present invention, wherein the compact micro light source image module is obtained via cutting the carrier board with a light source image module;

FIG. 7B and FIG. 7C are respectively a perspective view and a top view showing the second embodiment of the compact micro light source image module of the present invention;

FIG. 8A and FIG. 8B are respectively a perspective view and a top view showing a third embodiment of the compact micro light source image module of the present invention;

FIG. 9A and FIG. 9B are respectively a perspective view and a top view showing a fourth embodiment of the compact micro light source image module of the present invention;

FIG. 10A and FIG. 10B are diagrams schematically showing a third embodiment of the carrier board with a light source image module of the present invention;

FIG. 11A is a diagram schematically showing a fourth embodiment of the carrier board with a light source image module of the present invention;

FIG. 11B and FIG. 11C are respectively a perspective view and a top view showing a fifth embodiment of the compact micro light source image module of the present invention, wherein the compact micro light source image module is obtained via cutting the carrier board with light source image module shown in FIG. 11A;

FIGS. 12-14 are diagrams schematically showing various embodiments of an integrated carrier board with light source image modules of the present invention;

FIG. 15A is a diagram schematically showing the cutting lines added to the integrated carrier board shown in FIG. 13;

FIG. 15B and FIG. 15C are respectively a perspective view and a top view showing a sixth embodiment of the compact micro light source image module of the present invention;

FIG. 16A and FIG. 16B are respectively a perspective view and a top view showing a seventh embodiment of the compact micro light source image module of the present invention;

FIG. 17A and FIG. 17B are respectively a perspective view and a top view showing an eighth embodiment of the compact micro light source image module of the present invention;

FIG. 18A and FIG. 18B are respectively a perspective view and a top view showing a ninth embodiment of the compact micro light source image module of the present invention.

### DESCRIPTION OF THE PREFERRED EMBODIMENTS

The embodiments of the present invention will be further demonstrated in detail hereinafter in cooperation with the corresponding drawings. In the drawings and the specification, the same numerals represent the same or the like elements as much as possible. For simplicity and convenient labelling, the shapes and thicknesses of the elements may be exaggerated in the drawings. It is easily understood: the elements belonging to the conventional technologies and well known by the persons skilled in the art may be not particularly depicted in the drawings or described in the specification. Various modifications and variations made by the persons skilled in the art according to the contents of the present invention are to be included by the scope of the present invention.

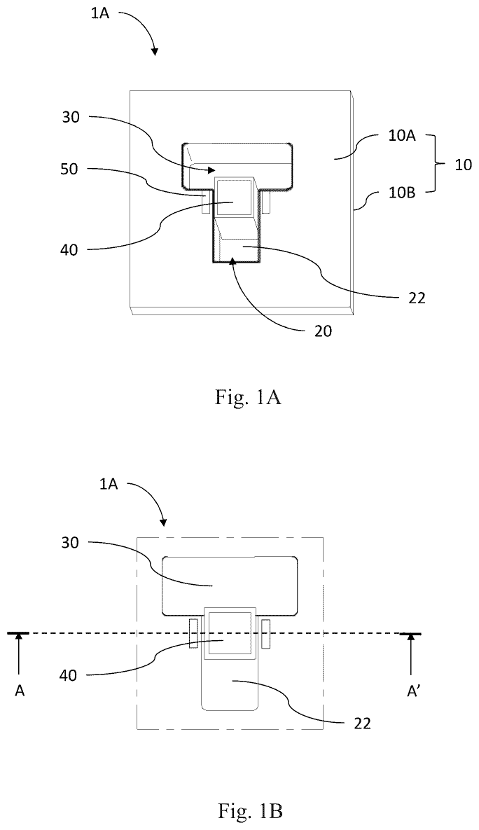

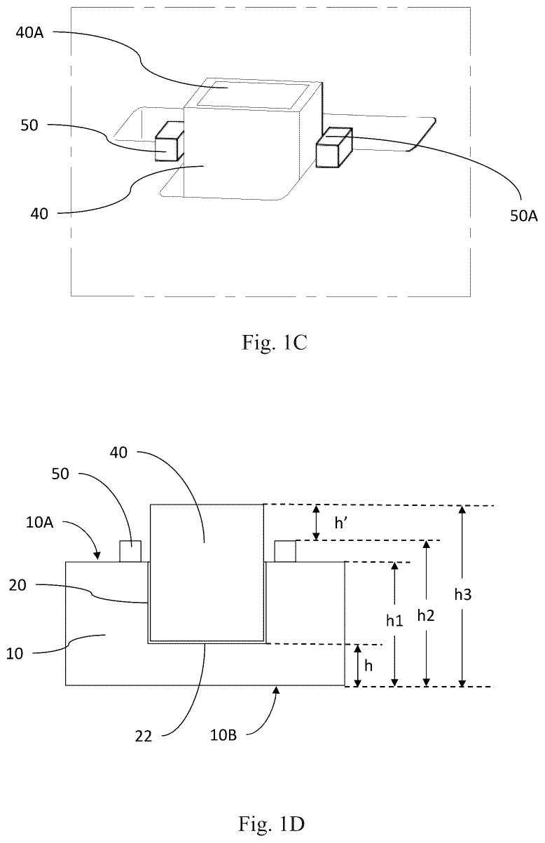

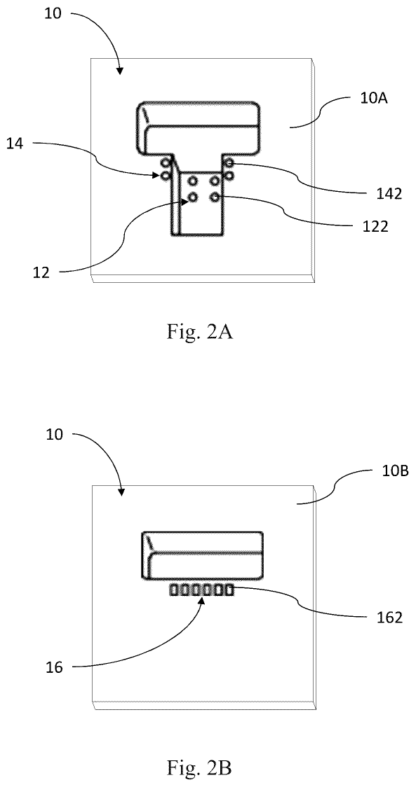

Below is introduced a carrier board with a light source image module according to a first embodiment of the present invention. Refer to FIGS. 1A-2B. In FIGS. 1A-1D, the carrier board with a light source image module 1A comprises a substrate 10, a cavity 20, a perforated section 30, an image sensor 40, and a light-emitting device 50. The substrate 10 has a first surface 10A and a second surface 10B opposite to the first surface 10A. The cavity 20 is formed on the substrate 10 and has a bottom surface 22. The altitude h of the bottom surface 22 is lower than the altitude h1 of the first surface 10A. The perforated section 30 is formed on at least a portion of the cavity 20. The perforated section 30 penetrates the first surface 10A and the second surface 10B and interconnects with at least a portion of the cavity 20. The image sensor 40 is partially disposed in the cavity 20 and partially disposed in the perforated section 30. The altitude h3 of the surface 40A of the image sensor 40 is higher than the altitude h1 of the first surface 10A. The image sensor 40 may be but is not limited to be a CMOS image sensor module. The light-emitting device 50 is disposed on a position of the first surface 10A, which is adjacent to the image sensor 40. The top surface 50A of the light-emitting device 50 is between the first surface 10A and the surface 40A of the image sensor 40. The difference between the altitude of the surface 50A of the light-emitting device 50 and the altitude of the surface 40A of the image sensor 40 is h′. The altitude h3 of the surface 40A of the image sensor 40 is larger than the altitude h2 of the surface 50A of the light-emitting device 50, The light-emitting device 50 may be but is not limited to be LED.

Refer to FIG. 2A and FIG. 2B simultaneously. In the carrier board with a light source image module 1A, the substrate 10 further includes a first electric-conduction route 12, a second electric-conduction route 14, and a third electric-conduction route 16. The first electric-conduction route 12 is disposed on the bottom surface 22 of the cavity 20, having a plurality of first circuit connection pads 122. The image sensor 40 is electrically connected with the plurality of first circuit connection pads 122. The second electric-conduction route 14 is disposed on a region of the first surface 10A, which is near the cavity 20, having a plurality of second circuit connection pads 142. The light-emitting device 50 is electrically connected with the plurality of second circuit connection pads 142. The third electric-conduction route 16 is disposed on the second surface 10B, having a plurality of third circuit connection pads 162. A portion of the plurality of third circuit connection pads 162 is connected with the plurality of first circuit connection pads 122. A portion of the plurality of third circuit connection pads 162 is connected with the plurality of second circuit connection pads 142. A portion of the plurality of third circuit connection pads 162 is the signal transmission connection pads of the image sensor 40. Another portion of the plurality of third circuit connection pads 162 is the power signal connection pads of the light-emitting device 50.

In some embodiments of the present invention, the carrier board with a light source image module 1A further comprises an encapsulation body, which may be but is not limited to be an opaque resin body or a transparent resin body.

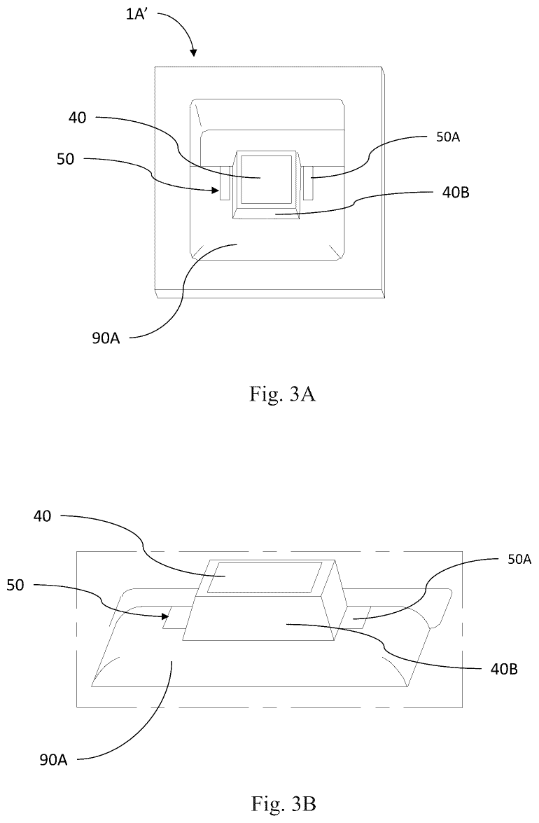

FIG. 3A is a perspective view schematically showing a carrier board with a light source image module 1A′ where an encapsulation body has been formed according to one embodiment of the present invention. FIG. 3B is a diagram schematically showing a carrier board with a light source image module 1A′ where an encapsulation body has been formed according to one embodiment of the present invention. Refer to FIG. 3A and FIG. 3B. In the carrier board with a light source image module 1A′, the encapsulation body 90A may be an opaque resin body, covering the surface 40B of the perimeter of the image sensor 40. The encapsulation body 90A does not cover the surface 50A of the light-emitting device 50. Thereby, the encapsulation body 90A can prevent the illumination light emitted by the light-emitting device 50 or the stray light from entering the imaging system of the image sensor 40 lest the image quality be affected.

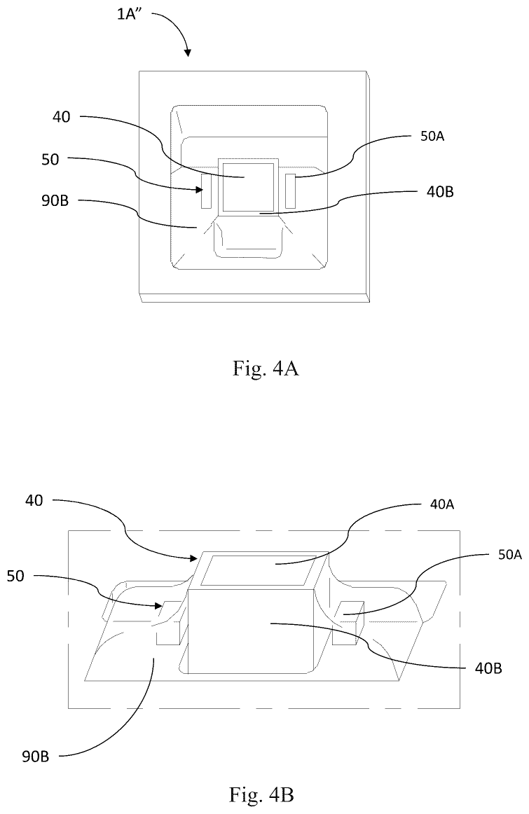

FIG. 4A is a perspective view schematically showing a carrier board with a light source image module 1A″ where an encapsulation body has been formed according to another embodiment of the present invention. FIG. 4B is a diagram schematically showing a carrier board with a light source image module 1A″ where an encapsulation body has been formed according to another embodiment of the present invention. Refer to FIG. 4A and FIG. 4B. In the carrier board with a light source image module 1A″, the encapsulation body 90B may be a transparent resin body, covering the surface 40B of the perimeter of the image sensor 40. The altitude of the encapsulation body 90B is higher than the altitude of the surface 50A of the light-emitting device 50 and lower than or equal to the altitude of the surface 40A of the image sensor 40.

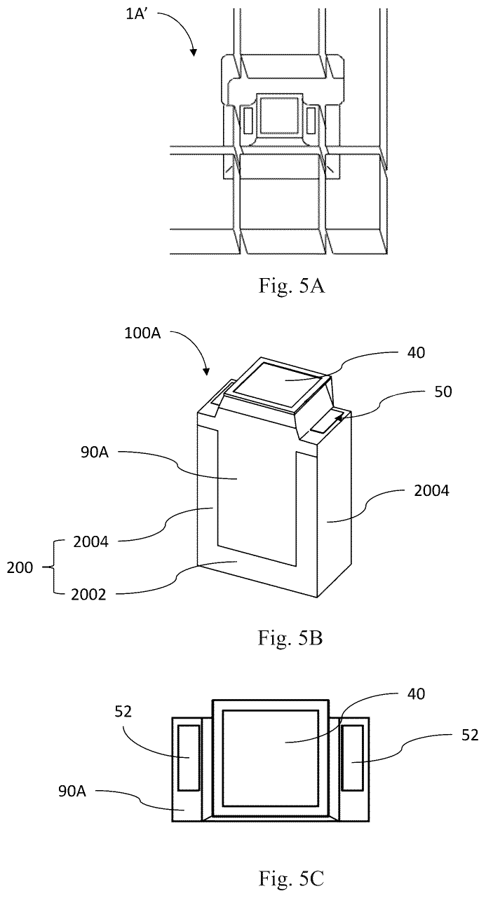

Refer to FIGS. 5A-5C. Below is introduced a first embodiment of a compact micro light source image module. The compact micro light source image module 100A is generated via cutting the carrier board with a light source image module 1A′ shown in FIG. 3A. The compact micro light source image module 100A comprises an interposer 200, an image sensor 40, the light-emitting devices 50, and the encapsulation body 90A. The interposer 200 includes a bottom base 2002 and at least one side carrier 2004, which are generated via cutting the substrate 10. The bottom base 2002 is formed by a portion of the cut cavity. The at least one side carrier 2004 is formed by a portion of the substrate 10, which neighbors the cavity 20. One side of the bottom base 2002 is joined with the side carrier 2004. The image sensor 40 is disposed on the bottom base 2002. The light-emitting device 50 is disposed on the surface of the at least one side carrier 2004. The encapsulation body 90A covers the image sensor 40 except the perimeter of the image sensor 40, which is corresponding to the at least one side carrier 2004, and the surround of the light-emitting device 50. In one embodiment, there may be one or two side carriers 2004. As shown in FIG. 5B and FIG. 5C, there are two side carriers 2004; two light-emitting elements 52 are respectively disposed on the two side carriers 2004; the encapsulation body 90A covers the perimeter of the image sensor 40, which is adjacent to one of the two side carriers 2004, or covers the perimeter of two sides of the image sensor 40 in form of a flats, arcs, or polygons.

The light-emitting device 50 may include one or more light-emitting elements 52. If the light-emitting device 50 includes several light-emitting elements 52, the light-emitting elements 52 may be disposed on the first surface 10A and at two sides of the image sensor 40, which are adjacent to the image sensor 40 but opposite to each other or disposed at two neighboring sides of the image sensor 40. The light-emitting elements 52 may generate illumination light respectively having different ranges of wavelengths according to different applications. The light-emitting elements 52 may be switched on respectively or turned on simultaneously according to requirement. For example, the light-emitting elements 52 may include white light LEDs, infrared LEDs, blue light LEDs, ultraviolet LEDs, or a combination thereof. In some embodiments, the light-emitting element 52 may be a naked LED chip or has secondary optical structures for modifying the light-output angle.

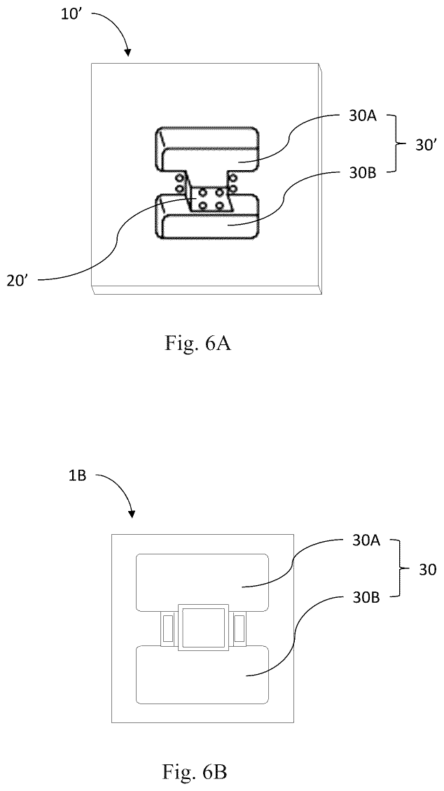

Refer to FIG. 6A and FIG. 6B. Below is introduced a second embodiment of a light source-imaging module-containing carrier board. The carrier board with light source image module 1B comprises a substrate 10′, a cavity 20′, a perforated section 30′, an image sensor 40′, and a light-emitting device 50′. The second embodiment is different from the first embodiment in the perforated section 30′. In the second embodiment, the perforated section 30′ includes a first perforated section 30A and a second perforated section 30B. The first perforated section 30A and the second perforated section 30B are respectively disposed on the upper side and the lower side of the cavity 20′. The other elements of the second embodiment have been introduced in the first embodiment and will not repeat herein.

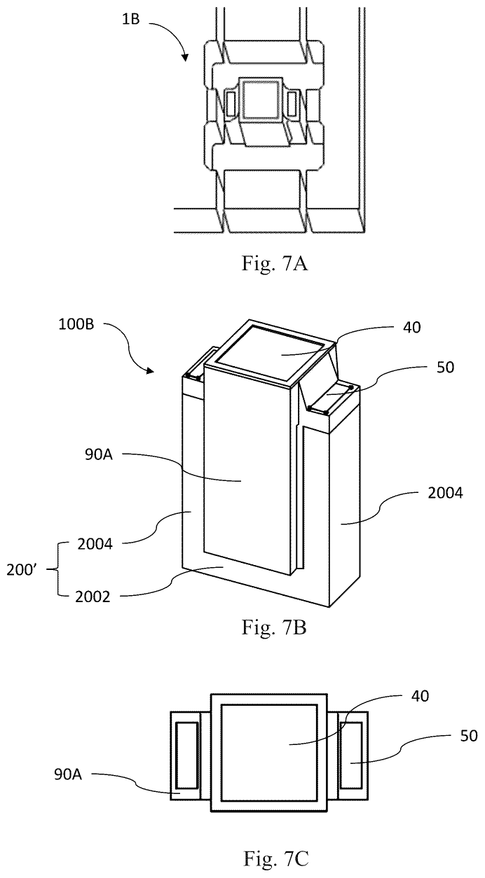

Refer to FIGS. 7A-7C. Below is introduced a second embodiment of a compact micro light source image module. The compact micro light source image module 100B is generated via cutting the carrier board with a light source image module 1B shown in FIG. 6B. The compact micro light source image module 100B of the second embodiment is different from the compact micro light source image module 100A of the first embodiment in that the size of the interposer 200′ is smaller than or equal to the size of the image sensor 40. In the second embodiment, after cutting, the size of the interposer 200′ approaches the size of the image sensor 40 in the region free of the light-emitting device 50. The parts below two sides of the image sensor 40 are locally hanging structures, whereby to minimize the module structure. The other elements of the second embodiment have been introduced in the first embodiment and will not repeat herein.

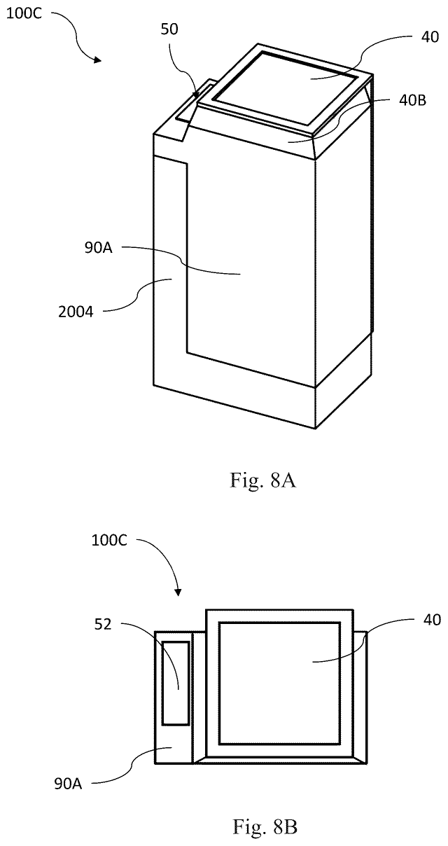

Refer to FIG. 8A and FIG. 8B. Below is introduced a third embodiment of a compact micro light source image module. The compact micro light source image module 100C of the third embodiment is different from the compact micro light source image module 100B of the first embodiment in that there is only one side carrier 2004 in the third embodiment. In the third embodiment, the light-emitting device 50 only has single light-emitting element 52; the light-emitting element 52 is disposed on the side carrier 2004; the encapsulation body 90A covers at least one side of the surface 40B of the perimeter of the image sensor 40. The other elements of the third embodiment have been introduced in the first embodiment and will not repeat herein.

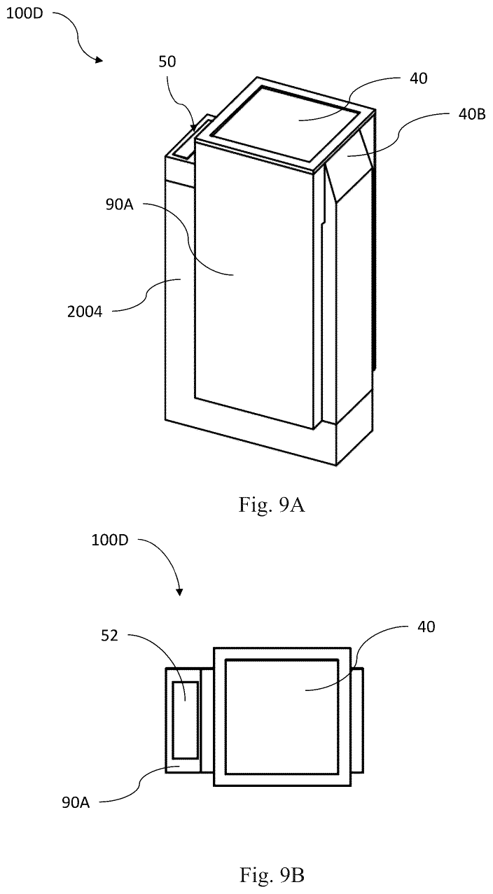

Refer to FIG. 9A and FIG. 9B. Below is introduced a fourth embodiment of a compact micro light source image module. The compact micro light source image module 100D of the fourth embodiment is different from the compact micro light source image module 100B of the second embodiment in that the interposer 200′ has only one side carrier 2004. In the fourth embodiment, the light-emitting device 50 only has single light-emitting element 52; the light-emitting element 52 is disposed on the side carrier 2004; the encapsulation body 90A covers at least one side of the surface 40B of the perimeter of the image sensor 40 or covers the image sensor 40 except the corresponding side carrier 2004 and the region corresponding to the perforated section 30.

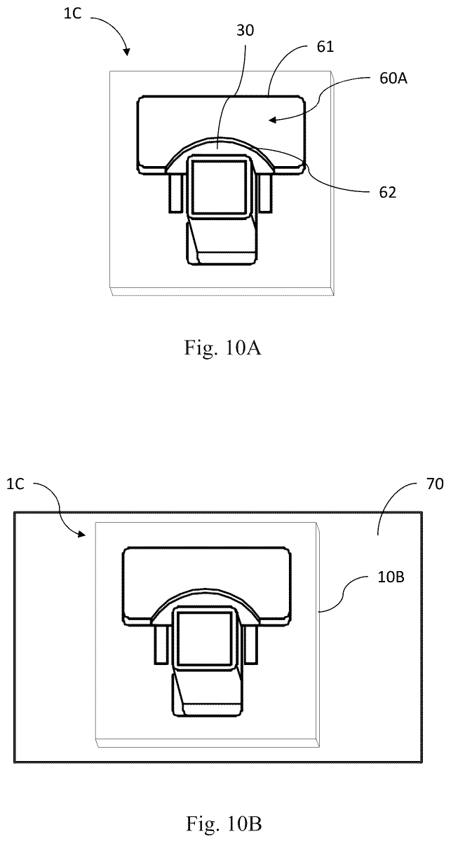

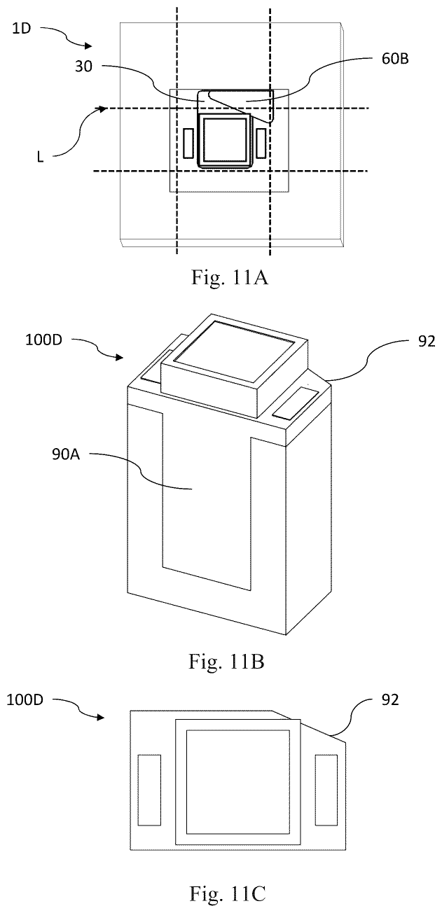

Refer to FIG. 10A and FIG. 10B. Below is introduced a third embodiment of a carrier board with a light source image module. The carrier board with a light source image module 1C of the third embodiment is different from the carrier board with a light source image module 1A of the first embodiment in that the carrier board with a light source image module 1C further comprises an insert element 60A and an overflow-proof carrier 70. The insert element 60A is inserted into the perforated section 30. It is easily understood: the shape of the insert element 60A is corresponding to the shape of the perforated section 30. The shape of at least one side of the insert element 60A may be formed corresponding to the shape of the micro light source-imaging module. For example, the shape of at least one side of the insert element 60A may be a flat, an arc, or a polygon. A first side 61 of the insert element 60A may match the boundary of the perforated section 30; a second side 62 of the insert element 60A is formed into a curved surface, whereby the encapsulation body may be disposed between the second side 62 of the insert element 60A and the image sensor 40. The overflow-proof carrier 70 is disposed on the second surface 10B. The overflow-proof carrier 70 may be but is not limited to be an adhesive carrier, a heat-resistant tape, or a release paper. The overflow-proof carrier 70 functions to prevent the encapsulation resin material from overflowing from the gap between the insert element 60A and the perforated section 30.

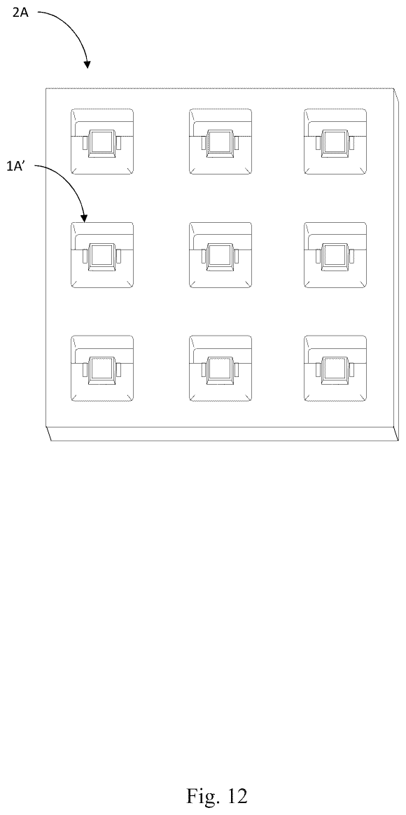

Refer to FIG. 11A. In a carrier board with a light source image module 1D, the insert element 60B may be but is not limited to be a mold having a polygonal shape or an irregular shape; the insert element 60B is not disposed at a symmetric position but at a corner of the perforated section 30. As shown in FIGS. 11A-11C, the carrier board with a light source image module 1D, which has the encapsulation body 90A, may be cut along cutting lines L to obtain the compact micro light source image modules 100D having a corresponding shape. A portion of the encapsulation body 90A may form a cut face 92, and the cut face 92 is not limited to be a plane or a curved surface.

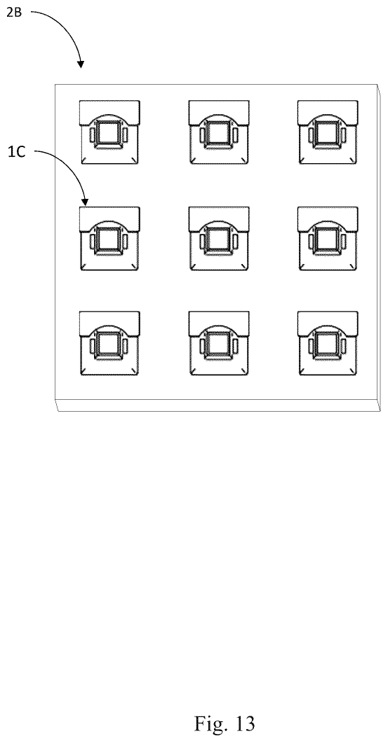

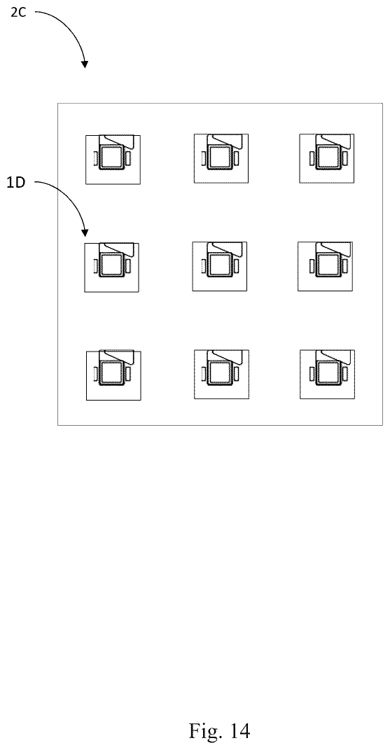

Below are introduced various embodiments of an integrated carrier board with light source image modules. Refer to FIGS. 12-14. The integrated carrier board with light source image modules comprises a plurality of the abovementioned carrier boards with a light source image module, wherein the plurality of carrier boards with a light source image module are integrated into an integral body to form an integrated carrier board. As shown in FIG. 12, the integrated carrier board with light source image modules 2A may comprise a plurality of carrier boards 1A′ (shown in FIG. 3A) and/or a plurality of carrier boards 1A″ (shown in FIG. 4A), wherein the plurality of carrier boards is combined to form an integral body. In FIG. 12, the carrier boards of the integrated carrier board 2A are represented by the plurality of carrier boards 1A′. However, the embodiment of FIG. 12 is only to exemplify the present invention, and the carrier boards of the integrated carrier board 2A are not limited to be the carrier boards 1A′. The present invention is not limited by the embodiment of FIG. 12. It is easily understood: the configuration of the integrated carrier board 2A may be adjusted according to requirement. As shown in FIG. 13, the integrated carrier board with light source image modules 2B may comprise a plurality of carrier boards 1C (shown in FIG. 10A). As shown in FIG. 14, the integrated carrier board with light source image modules 2C may comprise a plurality of carrier boards 1D (shown in FIG. 11A). The structures of the carrier boards of the integrated carrier board have been introduced in the abovementioned embodiments and will not repeat herein.

Below are introduced other embodiments of the compact micro light source image modules according to the diagrams and top views thereof.

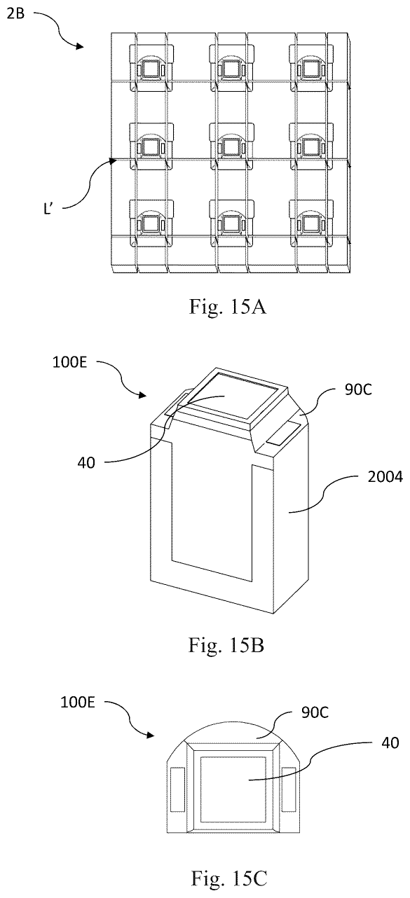

Refer to FIGS. 15A-15C. The compact micro light source image module 100E is generated via cutting the integrated carrier board 2B (shown in FIG. 13) along cutting lines L′. The compact micro light source image module 100E comprises an interposer 200, an image sensor 40, a light-emitting device 50, and an encapsulation body 90C. The interposer 200 includes a bottom base 2002 and two side carriers 2004. The compact micro light source image module 100E is different from the compact micro light source image module 100A in the encapsulation body 90C. The encapsulation body 90C covers the perimeter of the image sensor 40 and is inform of an arc on one side of the side carriers 2004. The other elements of the compact micro light source image module 100E have been introduced hereinbefore and will not repeat herein.

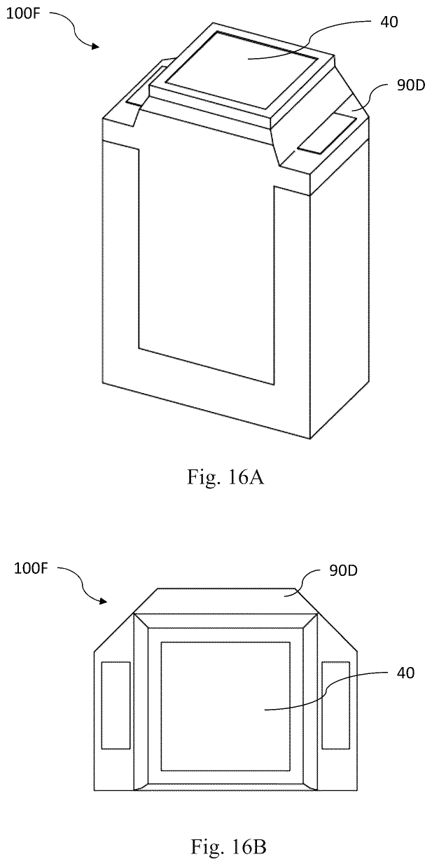

Refer to FIG. 16A and FIG. 16B. The compact micro light source image module 100F comprises an interposer 200, an image sensor 40, a light-emitting device 50, and an encapsulation body 90D. The interposer 200 includes a bottom base 2002 and two side carriers 2004. The compact micro light source image module 100F is different from the compact micro light source image module 100E in the encapsulation body 90D. The encapsulation body 90D covers the perimeter of the image sensor 40 and is in form of a polygonal shape on one side of the side carriers 2004. The other elements of the compact micro light source image module 100F have been introduced hereinbefore and will not repeat herein.

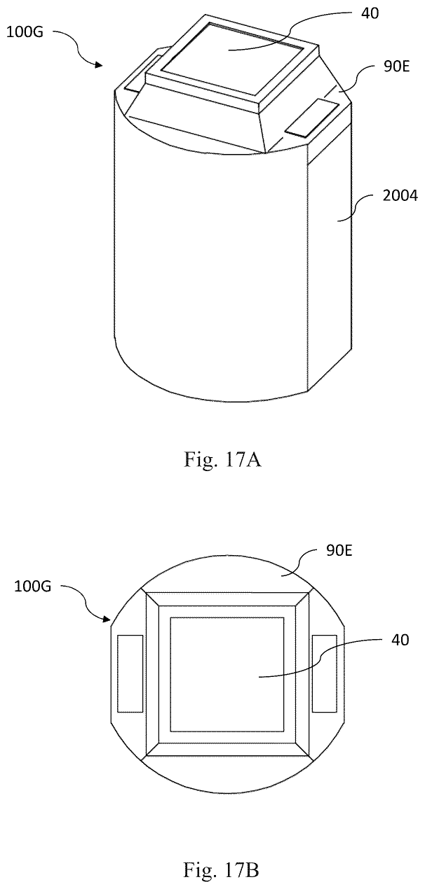

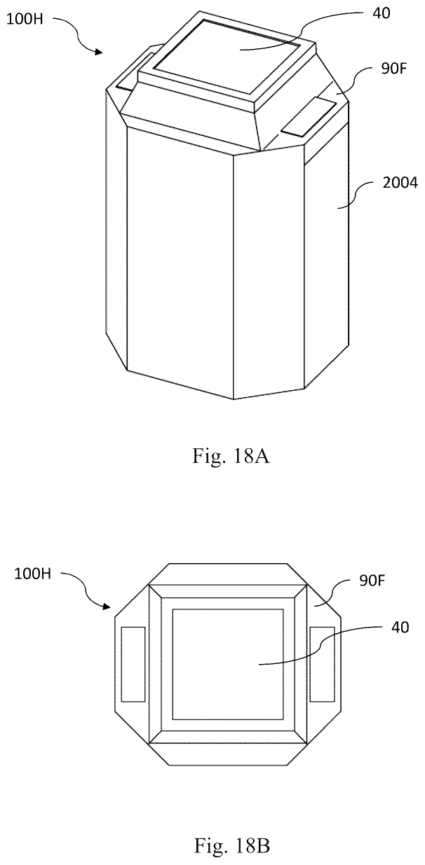

Refer to FIG. 17A and FIG. 17B. The compact micro light source image module 100G is different from the abovementioned compact micro light source image modules in the encapsulation body 90E. The encapsulation body 90E covers the perimeter of the image sensor 40 and is in form of arc shapes on two sides of the side carriers 2004. Refer to FIG. 18A and FIG. 18B. The compact micro light source image module 100H is different from the abovementioned compact micro light source image modules in the encapsulation body 90F. The encapsulation body 90F covers the perimeter of the image sensor 40 and is in form of polygonal shapes on one two sides of the side carriers 2004.

The embodiments described above are only to exemplify the present invention but not to limit the scope of the present invention. Any equivalent replacement or variation according to the specification or claims of the present invention is to be also included by the scope of the present invention.

While the invention is susceptible to various modifications and alternative forms, a specific example thereof has been shown in the drawings and is herein described in detail. It should be understood, however, that the invention is not to be limited to the form disclosed, but to the contrary, the invention is to cover all modifications, equivalents, and alternatives falling within the appended claims.

1. A carrier board with a light source image module, comprising
a substrate, having a first surface and a second surface opposite to the first surface;
a cavity, formed on the substrate, and having a bottom surface, wherein an altitude of the bottom surface is lower than an altitude of the first surface;
a perforated section, formed on at least a portion of the cavity, penetrating the first surface and the second surface, and interconnecting with at least a portion of the cavity;
an image sensor, partially disposed in the cavity and partially disposed in the perforated section, wherein the top surface of the image sensor is higher than the altitude of the first surface; and
a light-emitting device, disposed in a position of the first surface, which is adjacent to the image sensor, wherein the top surface of the light-emitting device is between the first surface and the surface of the image sensor.

2. The carrier board with a light source image module according to claim 1, wherein the substrate includes
a first electric-conduction route, disposed on the bottom surface of the cavity, and having a plurality of first circuit connection pads, wherein the image sensor is electrically connected with the plurality of first circuit connection pads;
a second electric-conduction route, disposed on a region of the first surface, which is near the cavity, and having a plurality of second circuit connection pads, wherein the light-emitting device is electrically connected with the plurality of second circuit connection pads; and
a third electric-conduction route, disposed on the second surface, and having a plurality of third circuit connection pads,
wherein a portion of the plurality of third circuit connection pads are connected with the plurality of first circuit connection pads; another portion of the plurality of third circuit connection pads are connected with the plurality of second circuit connection pads.

3. The carrier board with a light source image module according to claim 1, further comprising an encapsulation body, wherein the encapsulation body covers a surface of a perimeter of the image sensor; the encapsulation body does not cover a surface of the light-emitting device.

4. The carrier board with a light source image module according to claim 1, further comprising an encapsulation body, wherein the encapsulation body covers a surface of a perimeter of the image sensor; an altitude of the encapsulation body is higher than the altitude of the surface of the light-emitting device and lower than or equal to the altitude of the surface of the image sensor.

5. The carrier board with a light source image module according to claim 1, further comprising an insert element, wherein the insert element is inserted into the perforated section; a shape of the insert element is corresponding to a shape of the perforated section.

6. The carrier board with a light source image module according to claim 5, further comprising an overflow-proof carrier, wherein the overflow carrier is disposed on the second surface for covering the perforated section.

7. The carrier board with a light source image module according to claim 1, wherein the light-emitting device is a light-emitting element; the light-emitting element is disposed on a region of the first surface, which is near one side of the image sensor.

8. The carrier board with a light source image module according to claim 1, wherein the light-emitting device has two light-emitting elements; the two light-emitting elements are disposed on the first surface and at two sides of the image sensor, which are adjacent to the image sensor but opposite to each other, or at two neighboring sides of the image sensor, which are adjacent to the image sensor.

9. A compact micro light source image module, which is generated via cutting the carrier board with light source image module according to claim 3, and which comprises
an interposer, including a bottom base and at least one side carrier, which are generated via cutting the substrate, wherein the bottom base is formed by a portion of the cut cavity; the at least one side carrier is formed by a portion of the substrate, which neighbors the cavity; one side of the bottom base is joined with the side carrier;
an image sensor, disposed on the bottom base;
a light-emitting device, disposed on a surface of the at least one side carrier; and
an encapsulation body, covering the image sensor except a perimeter of the image sensor, which is corresponding to the at least one side carrier, and a perimeter of the light-emitting device.

10. The compact micro light source image module according to claim 9, wherein the at least one side carrier is one side carrier; the light-emitting device has a light-emitting element; the light-emitting element is disposed on the side carrier; the encapsulation body covers at least one side of the image sensor.

11. The compact micro light source image module according to claim 9, wherein the at least one side carrier is two side carriers; the light-emitting device has two light-emitting elements; the two light-emitting elements are respectively disposed on the two side carriers; the encapsulation body covers the perimeter of the image sensor and is in form of a flat, an arc, or a polygon one at least one side of the two side carriers.

12. The compact micro light source image module according to claim 9, wherein the at least one side carrier is two side carriers; the light-emitting device has two light-emitting elements; the two light-emitting elements are respectively disposed on the two side carriers; the encapsulation body covers the image sensor in perimeters of the two side carriers in form of a flat, an arc, or a polygon.

13. An integrated carrier board with light source image modules, comprising
a plurality of carrier board with light source image module according to claim 3, wherein the plurality of carrier boards with light source image module is integrated into an integral body functioning as an integrated carrier board.

14. The integrated carrier board with light source image modules according to claim 13, further comprising an insert element, wherein the insert element is inserted into the perforated section, and a shape of the insert element is corresponding to a shape of the perforated section.

15. The integrated carrier board with light source image modules according to claim 14, further comprising an overflow-proof carrier, wherein the overflow-proof carrier is disposed on the second surface and covers the perforated section.

16. A compact micro light source image module, which is generated via cutting the integrated carrier board with light source image module according to claim 13, and which comprises
an interposer, including a bottom base and at least one side carrier, wherein the bottom base is formed by a portion of the cut cavity; the at least one side carrier is formed by a portion of the substrate, which is near the cavity; one side of the bottom base is joined with the side carrier;
the image sensor, disposed on the bottom base;
the light-emitting device, disposed on a surface of the at least one side carrier; and
the encapsulation body, covering the image sensor except a perimeter of the at least side carrier and a perimeter of the light-emitting device.

17. The compact micro light source image module according to claim 16, wherein the at least one side carrier is one side carrier; the light-emitting device has a light-emitting element; the light-emitting element is disposed on the side carrier; the encapsulation body covers at least one side of the image sensor.

18. The compact micro light source image module according to claim 16, wherein the at least one side carrier is two side carriers; the light-emitting device has two light-emitting elements; the two light-emitting elements are respectively disposed on the two side carriers; the encapsulation body covers the perimeter of the image sensor and is n form of an arc or a polygon on one side of the two side carriers.

19. The compact micro light source image module according to claim 16, wherein the at least one side carrier is two side carriers; the light-emitting device has two light-emitting elements; the two light-emitting elements are respectively disposed on the two side carriers; the encapsulation body covers the perimeter of the image sensor and is in form of an arc or a polygon on two sides of the side carriers.

20. The compact micro light source image module according to claim 16, wherein the at least one side carrier is two side carriers; the light-emitting device has two light-emitting elements; the two light-emitting elements are respectively disposed on the two side carriers; a portion of the encapsulation body is a cut surface.
